(19) United States
(12) Patent Application Publication
(10) Pub. No.: US 2007/0053157 A1
(43) Pub. Date: Mar. 8, 2007

(54) Power supply device with an electromagnetic compatiblity heatsink

(75) Inventors: Alex Huang, Taoyuan City (TW); Sosa Chao, Taoyuan City (TW)

Correspondence Address: PATENTTM.US, P. O. BOX 82788, PORTLAND, OR, 97282-0788, US

(73) Assignee: ASIAN POWER DEVICES INC.

(21) Appl. No.: 11/222,295

(22) Filed: Sep. 7, 2005

(51) Int. Cl. H05K 7/20

(52) U.S. Cl. 361/688

(57) ABSTRACT

A power supply device with an electromagnetic compatibility heatsink, the power supply device has a circuit board, multiple electric elements and a housing and the electromagnetic compatibility heatsink has a shield and at lease one fin. The shield abuts the bottom of the circuit board and has at least one side edge. The at least one fin is formed on the side edge of the shield, extends up and touches the electric elements. When the electric elements converts alternating current to the direct current, electromagnetic waves and heat are generated. The heat is drawn from the electric elements to the fin and is conducted to the shield to dissipate and cool the electric elements. The shield blocks the electromagnetic waves and provides electromagnetic compatibility. The shield and the fin are formed together so the power supply device only needs one part improve electromagnetic compatibility and implement a cooling capability.

### BACKGROUND OF THE INVENTION

1. Field of the Invention

The present invention relates to a power supply device, and more particularly to a power supply device with a heatsink to improve the electromagnetic compatibility by blocking electromagnetic interference to or from the device.

2. Description of Related Art

A power supply device, such as a power supply or a power adapter are used widely in virtually all electronic equipment. The power supply device converts alternating current to direct current. With reference to FIG. 3, a power supply device comprises a circuit board (30), multiple electric elements (31), a piece of heat-conducting material (32), a heatsink (33), two electric cords and an optional housing. The circuit board (30) has a top surface and a bottom. The multiple electric elements (31) of the power supply device are mounted on the top surface of the circuit board (30), has a top and converts alternating current to direct current. The heatsink (33) is mounted on the top surface of the circuit board (30) and covers the electric elements (31). The piece of heat-conducting material (32) is mounted between the top of the electric elements (31) and the heatsink (33). One electric cord is connected to an external alternating current power source and the electric elements (31). The circuit board (30), the electric elements (31), the piece of heat-conducting material (32), the heatsink (33), a part of the electric cord are inside the housing.

Alternating current goes through the electric cord to the multiple electric elements (31) of the power supply device. The direct current goes through another electric cord to an electrical apparatus to which the cord is connected. During the converting process, the multiple electric elements (31) of the power supply device generates a great deal of heat. The heat passes through the piece of heat-conducting material (32) to the heatsink (33) and is dissipated to cool the electric elements (31) of the power supply device.

However, the electric elements (31) generates electromagnetic waves during the current converting process that result in electromagnetic interference. To prevent the electromagnetic waves from damaging or interfering with the operation of other electrical or electronic apparatus, a shield is mounted on the bottom of the circuit board (30). The shield blocks the radiated electromagnetic interference and provides electromagnetic compatibility.

However, the only function of the shield is to block the radiated electromagnetic interference and provide electromagnetic compatibility. The shield does not provide any cooling capability for the electric elements (31) of the power supply device. Consequently, the power supply device needs at least two additional parts, a shield and a heatsink (33) for the electric elements (31) of the power supply device to have electromagnetic compatibility and a cooling capability.

To overcome the shortcomings, the present invention provides an electromagnetic compatibility heatsink to obviate or mitigate the aforementioned problems.

### SUMMARY OF THE INVENTION

The primary objective of the present invention is to provide a power supply device with an electromagnetic compatibility heatsink, which has a heat dissipation capability and improves electromagnetic compatibility of a power supply device to which it is attached.

A power supply device with an electromagnetic compatibility heatsink in accordance with the present invention, the power supply device has a circuit board with a bottom, multiple electric elements of the power supply device and a housing and the electromagnetic compatibility heatsink has a shield and at lease one fin. The shield abuts the bottom of the circuit board and has at least one side edge. The at least one fin is formed on the side edge of the shield, extends up and touches the electric elements. When the electric elements of the power supply device converts alternating current to direct current, electromagnetic waves and heat are generated. The heat is drawn from the electric elements of the power supply device to the fin and is conducted to the shield to dissipate and cool the electric elements. The shield blocks the electromagnetic waves and provides electromagnetic compatibility. The shield and the fin are formed together so the power supply device only needs one part to improve electromagnetic compatibility and implement a cooling capability.

Other objectives, advantages and novel features of the invention will become more apparent from the following detailed description when taken in conjunction with the accompanying drawings.

### BRIEF DESCRIPTION OF THE DRAWINGS

FIG. 1 is an exploded perspective view of a power supply device with an electromagnetic compatibility heatsink in accordance with the present invention;

FIG. 2 is a top view of the power supply device in FIG. 1;

FIG. 3 is a cross sectional side view of a conventional power supply device in accordance with the prior art.

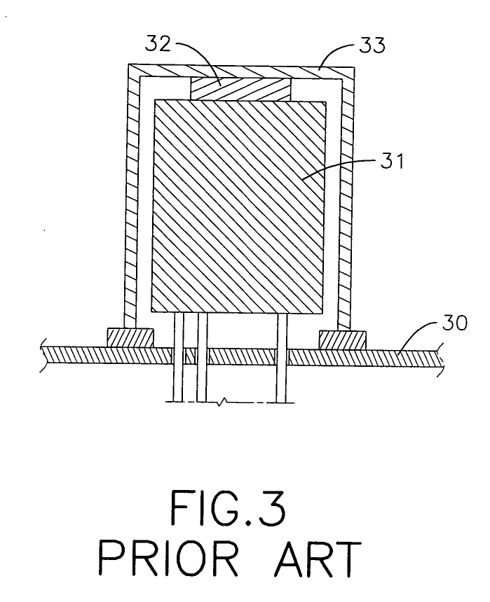

### DETAILED DESCRIPTION OF THE PREFERRED EMBODIMENT

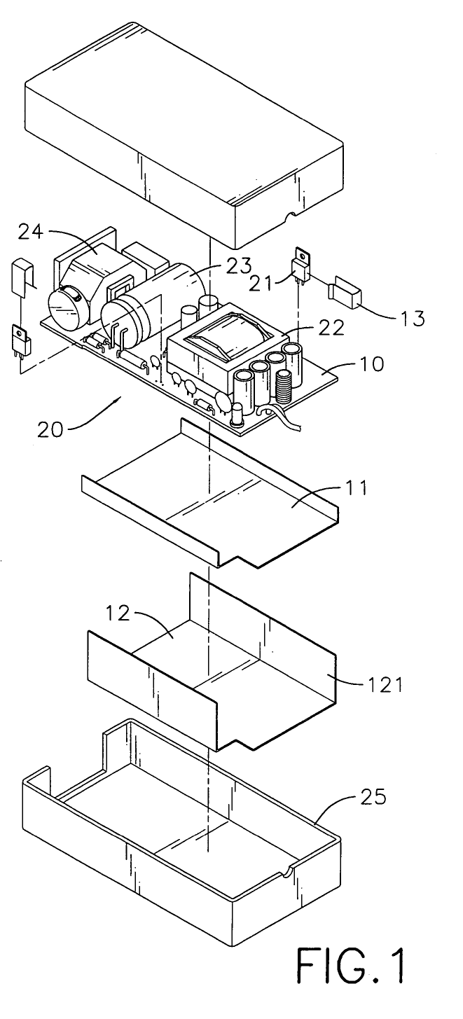

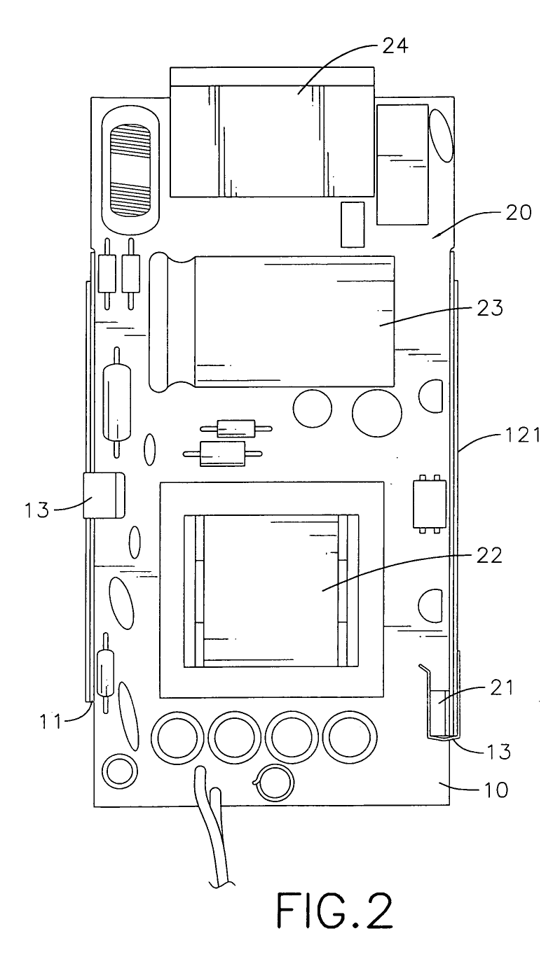

With reference to FIGS. 1 and 2, a power supply device with an electromagnetic compatibility heatsink in accordance with the present invention may be a power supply or a power adapter and has a circuit board (10), multiple electric elements (20), multiple electric cords, an optional housing (25) and an electromagnetic compatibility heatsink.

The heatsink has a shield (12), at lease one fin (121), at least one optional conductive clip (13) and an optional insulation layer (11).

The shield (12) is made of metal and has a top surface and at least one side edge.

Each fin (121) is made of metal, is formed at a side edge of the shield (12) and extends up and touches the electric elements (20) of the power device.

The at least one conductive clip (13) clips the electric elements (20) of the power device and a fin (121) so heat conducts from the electric elements (20) of the power device to the fin (121).

The insulation layer (11) is mounted between the bottom of the circuit board (10) and the top surface of the shield (12) to prevent shorts when the electric elements (20) of the power device touches the shield (12).

The circuit board (10) is mounted on the top surface of the shield next to the at least one fin (121) and has a top surface and a bottom.

The electric elements (20) of the power device converts alternating current to direct current, are mounted on the top surface of the circuit board (10) and abuts the fin (121) and has at least one transistor (21), a transformer (22), multiple capacitors (23) and a socket (24). The transistor (21) generates a great deal of heat amount when it operates so the conductive clip (13) clips the transistor (21) to the fin (121) to make the transistor (21) abut the fin (121) so the heat from the transistor (21) conducts to the fin (121).

The electric cords are coupled to the circuit board (10).

The circuit board (10), the insulation layer (11), the electric elements (20), a part of electric cord, the shield (12) and the fin (121) are inside the housing.

If the power supply is mounted inside an electrical apparatus, the power supply does not need the housing to be covered. If the power adapter is outside an electrical apparatus, the power adapter must have a housing to protect the power adapter components and make the power adapter look nice.

When the electric elements (20) of the power device converts alternating current to direct current, electromagnetic waves and heat are generated. The heat is drawn from the electric elements (20) of the power device to the fin (121) directly and through the shield (12). The fin (121) dissipates the heat to cool the electric elements (20) of the power device.

The shield (12) blocks the electromagnetic waves and improves the electromagnetic compatibility of the power supply and power adapter so the electromagnetic waves do not damage other electrical apparatus.

The shield (12) and the at least one fin (121) are formed together so that the power supply device only needs one part to have the electromagnetic compatibility and cooling function.

Even though numerous characteristics and advantages of the present invention have been set forth in the foregoing description together with details of the structure and function of the invention, the disclosure is illustrative only. Changes may be made in detail especially in matters of shape, size, and arrangement of parts within the principles of the invention to the full extent indicated by the broad general meaning of the terms in which the appended claims are expressed.

What is claimed is:

1. A power supply comprising:
a circuit board;
multiple electric elements mounted on top surface of the circuit board;
multiple electric cords coupled to the circuit board; and
an electromagnetic compatibility heatsink having:
a shield being attached to a bottom of the circuit board; and
at least one fin formed at a side edge of the shield to touch at least one of the multiple electric elements.

2. The power supply as claimed in claim 1 further having at least one conductive clip that clips at least one of the electric elements and one of the fins together so heat conducts from the at least one of the electric elements to the fin.

3. The power supply as claimed in claim 1 further having an insulation layer being mounted between the circuit board and the shield.

4. A power adapter comprising:
a circuit board;
multiple electric elements mounted on top surface of the circuit board;
multiple electric cords coupled to the circuit board;
an electromagnetic compatibility heatsink having:
a shield being attached to a bottom of the circuit board; and
at lease one fin formed at a side edge of the shield to touch at least one of the electric elements; and
a housing covering the circuit board with the electric elements and the electromagnetic compatibility heatsink inside.

5. The power adapter as claimed in claim 4 further having at least one conductive clip that clips at least one of the electric elements and one of the fins together so heat conducts from the at least one of the electric elements to the fin.

6. The power adapter electromagnetic compatibility heatsink as claimed in claim 5 further having an insulation layer being mounted between the circuit board and the shield.
